(19) United States
(12) Patent Application Publication
(10) Pub. No.: US 2015/0349095 A1
(43) Pub. Date: Dec. 3, 2015

(54) METHODS FOR FABRICATING INTEGRATED CIRCUITS WITH NONVOLATILE MEMORY DEVICES

(71) Applicant: GLOBALFOUNDRIES Singapore Pte. Ltd.

(72) Inventors: Chiew Wah Yap, Singapore (SG); Hai Cong, Singapore (SG); Zhehui Wang, Singapore (SG); Thomas Wang, Singapore (SG); Wei Loong Loh, Singapore (SG)

(73) Assignee: GLOBALFOUNDRIES Singapore Pte. Ltd.

(21) Appl. No.: 14/294,984

(22) Filed: Jun. 3, 2014

(51) Int. Cl. H01L 29/66; H01L 21/283; H01L 27/115; H01L 29/40

(52) U.S. Cl. CPC H01L 29/66825; H01L 29/401; H01L 21/283; H01L 27/11521

(57) ABSTRACT

Methods for fabricating integrated circuits are provided. An exemplary method for fabricating an integrated circuit includes forming a stack gate structure overlying a semiconductor substrate. The method forms a select gate material overlying the stack gate structure and the semiconductor substrate and having a planar surface overlying the stack gate structure. The method includes anisotropically etching the select gate material to define a select gate adjacent the stack gate structure, wherein the select gate is formed with a planar upper surface.

### TECHNICAL FIELD

The present disclosure generally relates to methods for fabricating integrated circuits, and more particularly relates to methods for fabricating integrated circuits with nonvolatile memory devices having improved select gates.

### BACKGROUND

Integrated circuits find application in many of today's consumer electronics, such as cell phones, video cameras, portable music players, printers, computers, calculators, automobiles, etc. Integrated circuits may include a combination of active devices, passive devices and their interconnections.

In some instances, integrated circuits may take the form of nonvolatile memory, which can be an integrated circuit designed to store digital data in the form of an electrical charge. Uniquely, a nonvolatile memory charge remains in storage even after the power is turned off. Accordingly, the use of nonvolatile memory devices can be particularly advantageous for power saving applications or in applications where power can be interrupted.

Nonvolatile flash memory usually takes one of two forms, a stack gate form or a split-gate form. Nonvolatile memory cells utilizing the stack gate structure typically employ a planar configuration wherein a control gate lies over a floating gate in a stack and a select gate is formed adjacent the control/floating stack gate.

In conventional fabrication processes, control/floating stack gates are formed and a select gate material is deposited over the control/floating stack gates. A mask is typically deposited and patterned over the select gate material before a portion of the select gate material is selectively etched with respect to the mask. Then, a low-selectivity etch is performed to further recess the select gate material and to remove the mask. Thereafter, a high-selectivity etch is performed to define the select gates without etching the control/floating stack gates. The conventional process requires tight process control to avoid the formation of “horns” or vertical artifacts extending upward from the upper surfaces of the select gates that result from delayed or uneven etching of the mask. Also, tight process control is necessary to avoid forming the select gates with sloping, i.e., non-planar or non-horizontal, upper surfaces. An example of conventional processing defects is shown in FIG. 1. As shown, a semiconductor substrate 11 undergoes processing to form a control/floating stack gate 12. Then, select gates 14 are formed around the stack gate 12. As shown, one select gate 14 has a sloping, non-planar, non-horizontal upper surface 16 and the other select gate 14 has a horn 18.

Accordingly, it is desirable to provide improved methods for fabricating integrated circuits having nonvolatile memory devices. Also, it is desirable to provide methods for fabricating integrated circuits having select gates with substantially planar upper surfaces. In addition, it is desirable to provide methods for fabricating integrated circuits that include forming a select gate material with a planar surface before etching the select gate material to form select gates. Furthermore, other desirable features and characteristics will become apparent from the subsequent detailed description and the appended claims, taken in conjunction with the accompanying drawings and the foregoing technical field and background.

### BRIEF SUMMARY

Methods for fabricating integrated circuits are provided. An exemplary method for fabricating an integrated circuit includes forming a stack gate structure overlying a semiconductor substrate. The method forms a select gate material overlying the stack gate structure and the semiconductor substrate and having a planar surface overlying the stack gate structure. The method includes anisotropically etching the select gate material to define a select gate adjacent the stack gate structure, wherein the select gate is formed with a planar upper surface.

In another embodiment, a method for fabricating an integrated circuit is provided and includes depositing a tunnel dielectric layer overlying a semiconductor substrate, depositing a floating gate layer overlying the tunnel dielectric layer, depositing an intergate dielectric layer overlying the floating gate layer, depositing a control gate layer overlying the intergate dielectric layer, and depositing a cap layer overlying the control gate layer. The method further includes etching the cap layer, control gate layer, intergate dielectric layer, floating gate layer, and tunnel dielectric layer to form stack gate structures including a control gate and a floating gate. The method deposits a select gate material overlying the stack gate structures and the semiconductor substrate. Further, the method recesses the select gate material and forms the select gate material with a planar recessed surface. The method includes anisotropically etching the select gate material to define a select gate adjacent each stack gate structure.

In accordance with another embodiment, a method for fabricating an integrated circuit including a non-volatile memory is provided. The method includes forming a stack gate structure including control gate overlying a floating gate and overlying a semiconductor substrate. The method conformally deposits a select gate material overlying the stack gate structure and the semiconductor substrate. The select gate material has substantially vertical wall defining a lateral thickness from the stack gate structure. The method further includes recessing the select gate material and forming the select gate material with a planar recessed surface. Also, the method includes anisotropically etching the select gate material to define a select gate adjacent the stack gate structure. The select gate has a thickness equal to the lateral thickness.

### BRIEF DESCRIPTION OF THE DRAWINGS

Embodiments of methods for fabricating integrated circuits with nonvolatile memory devices will hereinafter be described in conjunction with the following drawing figures, wherein like numerals denote like elements, and wherein:

FIG. 1 illustrates, in cross section, a portion of a conventionally fabricated integrated circuit; and

FIGS. 2-11 illustrate, in cross section, a portion of an integrated circuit and method steps for fabricating the integrated circuit in accordance with various embodiments herein.

### DETAILED DESCRIPTION

The following detailed description is merely exemplary in nature and is not intended to limit the methods for fabricating integrated circuits as claimed herein. Furthermore, there is no intention to be bound by any expressed or implied theory presented in the preceding technical field, background or brief summary, or in the following detailed description.

In accordance with the various embodiments herein, improved methods for fabricating integrated circuits having nonvolatile memory devices are provided. Generally, the following embodiments relate to the formation of an integrated circuit including a stack gate nonvolatile memory device. In an exemplary embodiment, the methods for fabricating integrated circuits include formation of a select gate material overlying stack gate structures. Further, the exemplary methods include recessing the select gate material to establish a recessed planar surface. The exemplary methods include anisotropically etching the select gate material to form select gates adjacent the stack gate structures. As a result, the exemplary methods provide for forming select gates having substantially planar upper surfaces. In an exemplary embodiment, the select gates are formed with substantially horizontal upper surfaces and substantially vertical sidewalls. As used herein, terms such as “horizontal” and “vertical” describe the orientation and/or location of a feature or element within the consistent but arbitrary frame of reference illustrated by the drawings. Further, the exemplary methods allow for relaxed process control as compared to conventional processing. Specifically, the exemplary methods avoid use of a mask to define the select gates and avoid use of etches with varying selectivity toward the mask.

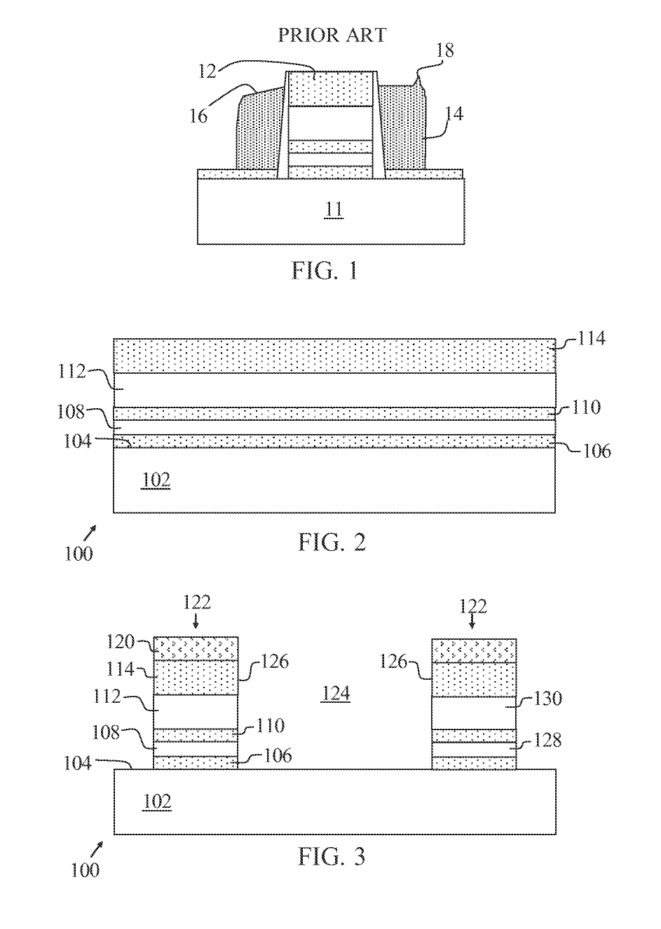

FIGS. 2-11 illustrate sequentially methods for fabricating an integrated circuit having a stack gate nonvolatile memory device in accordance with various embodiments herein. The drawings are semi-diagrammatic and not to scale and, particularly, some of the dimensions are for the clarity of presentation and are shown exaggerated in the drawings. Similarly, although the views in the drawings for ease of description generally show similar orientations, this depiction in the drawings is arbitrary. Generally, the integrated circuit can be operated in any orientation. Various steps in the design and composition of integrated circuits are well known and so, in the interest of brevity, many conventional steps will only be mentioned briefly herein or will be omitted entirely without providing the well known process details. Further, it is noted that integrated circuits include a varying number of components and that single components shown in the illustrations may be representative of multiple components.

Turning now to FIG. 2, in an exemplary embodiment, the process of fabricating an integrated circuit 100 includes providing a semiconductor substrate 102. The semiconductor substrate 102 for example is a silicon material as typically used in the semiconductor industry, e.g., relatively pure silicon as well as silicon admixed with other elements such as germanium, carbon, and the like. Alternatively, the semiconductor material can be germanium, gallium arsenide, or the like. The semiconductor material may be provided as a bulk semiconductor substrate, or it could be provided on a silicon-on-insulator (SOI) substrate, which includes a support substrate, an insulator layer on the support substrate, and a layer of silicon material on the insulator layer. Further, the semiconductor substrate 102 may optionally include an epitaxial layer (epi layer). The semiconductor substrate 102 has an upper surface 104.

A dielectric layer, such as a tunnel dielectric layer 106, is deposited overlying the upper surface 104 of the semiconductor substrate 102. As used herein “overlying” means “on” and “over”. In this regard, the tunnel dielectric layer 106 may lie directly on the upper surface 104 of the semiconductor substrate 102 such that it makes physical contact with the upper surface 104 or it may lie over the upper surface 104 such that another material layer, for example, another dielectric layer, is interposed between the upper surface 104 and the tunnel dielectric layer 106. As used herein, terms such as “over”, “overlying”, “upper” and “top” describe the orientation and/or location of a feature or element within the consistent but arbitrary frame of reference illustrated by the drawings. An exemplary tunnel dielectric layer 106 is silicon oxide. An exemplary tunnel dielectric layer 106 has a thickness of from about 20 Angstrom (A) to about 30 Å. In an exemplary embodiment, the tunnel dielectric layer 106 is formed by thermal oxidation, atomic layer deposition (ALD), chemical vapor deposition (CVD), physical vapor deposition (PVD), or by another suitable method.

In FIG. 2, a charge-trapping layer 108 is deposited over the tunnel dielectric layer 106. An exemplary charge-trapping layer 108 is silicon nitride, tantalum oxide, strontium titanate, or hafnium oxide. The exemplary charge-trapping layer 108 is formed with a thickness of from about 30 Å to about 50 Å in an exemplary embodiment. The charge-trapping layer 108 can be formed, for example, by chemical vapor deposition (CVD). In another embodiment, an intergate dielectric layer 110 is deposited over the charge-trapping layer 108. An exemplary intergate dielectric layer 110 is silicon oxide. Further, an exemplary intergate dielectric layer 110 is formed with a thickness of from about 20 Å to about 40 Å. In an exemplary embodiment, the intergate dielectric layer 110 is formed by chemical vapor deposition (CVD). As is well known, the intergate layer will service to insulate the floating gate from the control gate after gate formation.

As shown in FIG. 2, a conductive layer 112 is deposited over the intergate dielectric layer 110 in an exemplary embodiment. An exemplary conductive layer 112 is polysilicon, though it can be any conventional material including doped and undoped semiconducting materials (such as, for example, polysilicon, amorphous silicon, or silicon germanium), a metal, a metallic alloy, a silicide, a metal nitride, a metal oxide, a carbon nanotube, or a combination thereof. If the conductive layer 112 includes a metal, the metal may include copper, tungsten, aluminum, aluminum alloy, palladium, titanium, tantalum, nickel, cobalt, and molybdenum. Furthermore, if the conductive layer 112 includes a metal silicide, the metal silicide may include copper silicide, tungsten silicide, aluminum silicide, palladium silicide, titanium silicide, tantalum silicide, nickel silicide, cobalt silicide, erbium silicide, and molybdenum silicide. Other materials, which may be known to those skilled in the art for gate structures, may also be used for the conductive layer 112. Generally, the conductive layer 112 can be formed by chemical vapor deposition (CVD), physical vapor deposition (PVD), silicidation, plating, and/or atomic layer deposition (ALD). The conductive layer 112 may also include a multilayer structure and/or a dual structure. An exemplary conductive layer 112 has a thickness of about 80 Å to about 100 Å.

In another exemplary embodiment, a cap layer 114 is deposited over the conductive layer 112. An exemplary cap layer 114 is silicon oxide. The cap layer 114 has a thickness of from about 50 Å to about 80 Å, in an embodiment. The cap layer 114 can be deposited by a chemical vapor deposition (CVD) process using tetraethylorthosilicate (TEOS) and ozone as the reactive gases.

A mask layer is deposited, as illustrated in FIG. 3, and is patterned to form closed mask segments 120 overlying the cap layer 114. The cap layer 114, conductive layer 112, intergate dielectric layer 110, charge-trapping layer 108, and tunnel dielectric layer 106 are then etched. Specifically, an anisotropic etch selective to etching layers 114, 112, 110, 108, and 106 relative to closed mask segments 120 is performed and forms stack gate structures 122 separated by a gap 124. As shown, the stack gate structures 122 have substantially vertical sidewalls 126. In FIG. 3, the charge-trapping layer 108 forms a floating gate 128 in each stack gate structure 122 and the conductive layer 112 forms a control gate 130 in each stack gate structure 122.

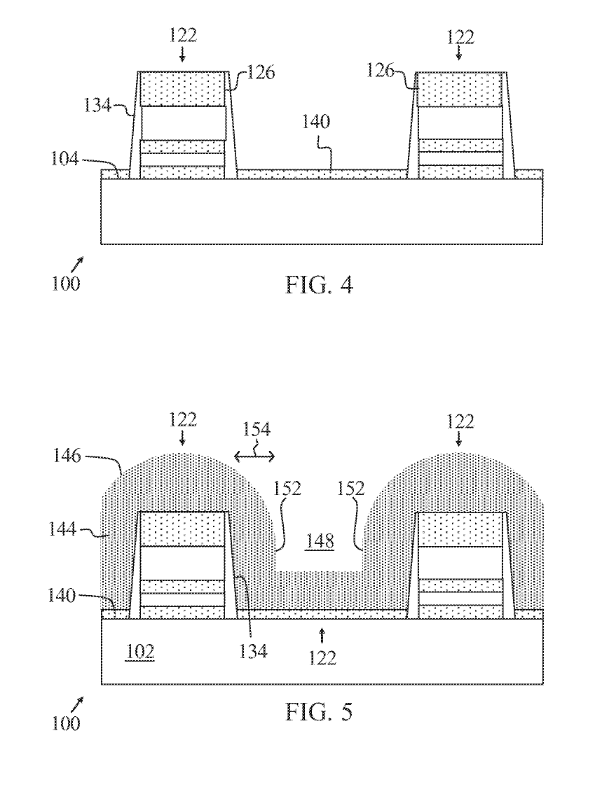

The process continues in FIG. 4 with the formation of spacers 134 adjacent the sidewalls 126 of the stack gate structures 122. In an exemplary embodiment, the closed mask segments 120 are removed from the stack gate structures 122 and a spacer-forming material is deposited over the stack gate structures 122 and the upper surface 104 of the semiconductor substrate 102. The exemplary deposition process is conformal such that the spacer-forming material is formed on the respective sidewalls 126 of the stack gate structures 122. For example, the spacer-forming material may be deposited by chemical vapor deposition (CVD). An exemplary spacer-forming material is silicon nitride, though any suitable material may be used. After the spacer-forming material is deposited, it is etched to form the spacers 134 adjacent each sidewall 126. In an exemplary process, the spacer-forming material is etched by a reaction ion etch (RIE) process.

After formation of the spacers 134, a select gate dielectric layer 140 is formed over the semiconductor substrate 102. An exemplary select gate dielectric layer 140 is deposited over the upper surface 104 of the semiconductor substrate 102. An exemplary select gate dielectric layer 140 may include silicon oxide, silicon oxynitride, a silicon oxide/nitride/oxide stack, a high-k dielectric material (i.e., a material having a dielectric constant value greater than silicon oxide), or a combination thereof. The select gate dielectric layer 140 can be formed by thermal oxidation, atomic layer deposition (ALD), chemical vapor deposition (CVD), physical vapor deposition (PVD), or by other suitable methods. An exemplary select gate dielectric layer 140 has a thickness of from about 30 Å to about 50 Å.

In FIG. 5, a select gate material 144 is formed over the stack gate structures 122 and the select gate dielectric layer 140. An exemplary select gate material 144 is polysilicon though it can be any conventional material including doped and undoped semiconducting materials (such as, for example, polysilicon, amorphous silicon, or silicon germanium), a metal, a metallic alloy, a silicide, a metal nitride, a metal oxide, a carbon nanotube, or a combination thereof. If the select gate material 144 includes a metal, the metal may include copper, tungsten, aluminum, aluminum alloy, palladium, titanium, tantalum, nickel, cobalt, and molybdenum. Furthermore, if the select gate material 144 includes a metal silicide, the metal silicide may include copper silicide, tungsten silicide, aluminum silicide, palladium silicide, titanium silicide, tantalum silicide, nickel silicide, cobalt silicide, erbium silicide, and molybdenum silicide. Other materials, which may be known to those skilled in the art for gate structures, may also be used for the select gate material 144. Generally, the select gate material 144 can be formed by chemical vapor deposition (CVD), physical vapor deposition (PVD), silicidation, plating, and/or atomic layer deposition (ALD). The select gate material 144 may also include a multilayer structure and/or a dual structure.

As shown, conformal deposition of the select gate material 144 results in the formation of a non-planar upper surface 146 of the select gate material 144. Further, the exemplary non-planar upper surface 146 defines a depression or trough 148 located at or within the gap 124 between the stack gate structures 122. Further, the exemplary non-planar upper surface 146 includes substantially vertical sidewall portions 152 bounding the trough 148. As shown, the select gate material 144 is formed with a maximum thickness indicated by double headed arrow 154 between the spacer 134 and the vertical sidewall portions 152 of the select gate material 144. In an exemplary embodiment, the thickness 154 is from about 100 Å to about 500 Å.

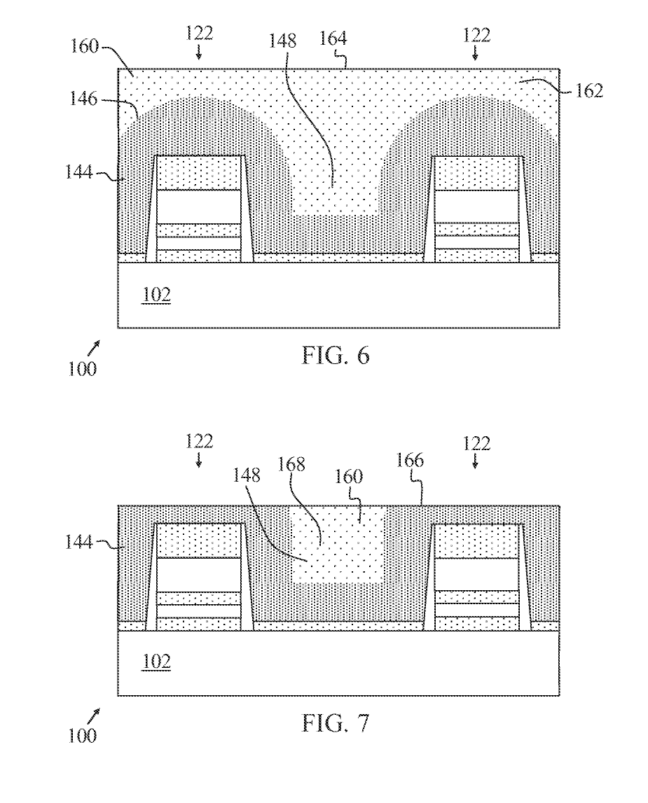

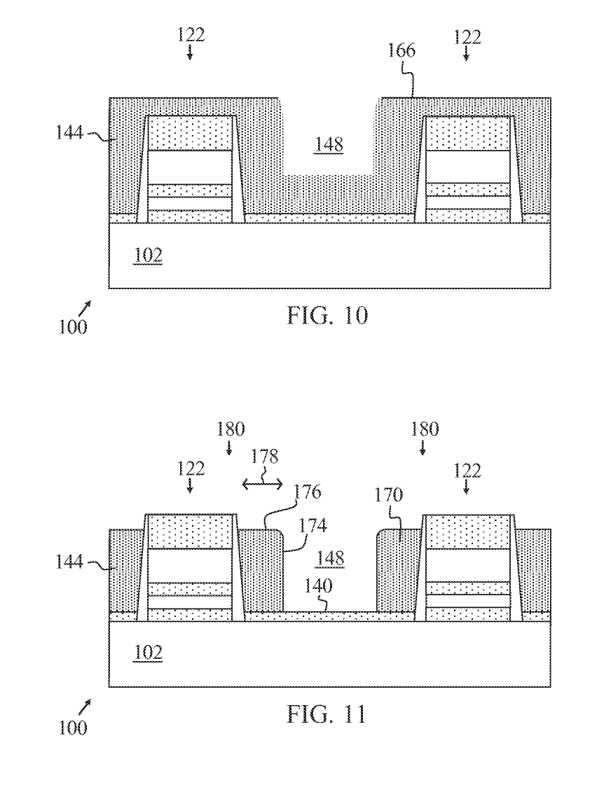

FIGS. 2-5 illustrate initial processes for fabricating an integrated circuit 100 and result in the formation of the select gate material 144 over stack gate structures 122. FIGS. 6-9 illustrate an embodiment for forming select gates adjacent to the stack gate structures, while FIGS. 10-11 illustrate an alternate embodiment for forming select gates adjacent to the stack gate structures.

As illustrated in FIG. 6, a planarizing layer 160 is formed over the select gate material 144. As shown, the planarizing layer 160 is deposited onto the non-planar upper surface 146 of the select gate material 144. The planarizing layer 160 fills the trough 148 between the stack gate structures 122 and forms an overburden portion 162 overlying the stack gate structures 122. Further, the planarizing layer 160 is formed with a planar top surface 164. An exemplary planarizing layer 160 is self-planarizing. As used herein, a “self-planarizing” material forms a planar upper surface without application of external force other than gravity.

An exemplary planarizing layer 160 is an organic dielectric layer (ODL) or an organic planarization layer (OPL). The exemplary planarizing layer 160 can be an organic material including C, 0, and H, and optionally including Si and/or F. Suitable organic dielectric materials that can be employed as the planarizing layer 160 include, but are not limited to: diamond-like carbon (DLC), fluorinated DLC, polyimides, fluorinated polyimides, parylene-N, parylene-F, benzocyclobutanes, poly(arylene ethers), polytetrafluoroethylene (PTFE) poly(naphthalenes), poly(norbornenes), foams of polyimides, organic xerogels, porous PTFE and other nano-, micro- or macro-porous organic materials. The planarizing layer 160 may also be formed from photoresist.

The planarizing layer 160 can be formulated to exhibit low viscosity so that the upper surface is self-planarizing notwithstanding underlying topographic features, i.e., the stack gate structures 122. The thickness of the planarizing layer 160 can be selected to be greater than the depth of the trough 148 so that the select gate material 144 is completely covered by the planarizing layer 160. In an exemplary embodiment, the thickness of the planarizing layer 160 over the trough 148 is from about 500 Å to about 2000 Å and the thickness of the planarizing layer 160 is from about 600 Å to about 1000 Å over the stack gate structures 122.

In an exemplary process, the planarizing layer 160 is formed by spin coating. Other processes for forming the planarizing layer 160 include chemical vapor deposition (CVD), plasma vapor deposition (PVD), sputtering, dip coating, brushing, spraying and other blanket deposition techniques.

Turning to FIG. 7, the planarizing layer 160 and the select gate material 144 are recessed to form a recessed surface 166. As shown, the recessed surface 166 is defined by both the planarizing layer 160 and the select gate material 144. The planarizing layer 160 and the select gate material 144 may be recessed by a non-selective etchant, i.e., an etchant that etches the planarizing layer 160 and the select gate material 144 at the same rate. Because the planarizing layer 160 is initially formed with a planar top surface 164, the recess performed with a non-selective etchant results in a planar recessed surface 166. In an exemplary embodiment, the non-selective etch process is timed so that the underlying stack gate structures 122 are not exposed by the etch process. As shown, a portion 168 of the planarizing layer 160 remains in the trough 148.

Alternatively, the planarizing layer 160 and the select gate material 144 may be planarized by a chemical-mechanical planarization (CMP) process to form the planar recessed surface 166. In such an embodiment, it is not necessary that the planarizing layer 160 be initially formed with a planar top surface 164.

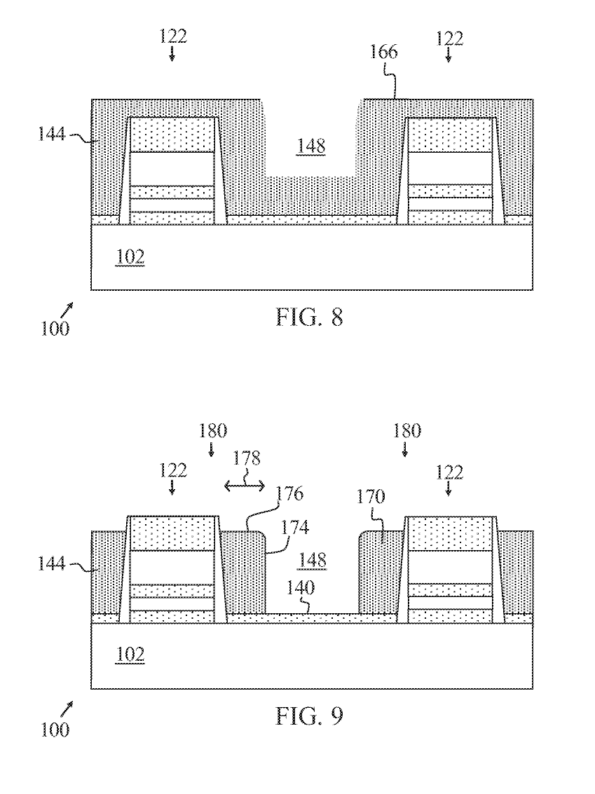

As shown in FIG. 8, in an exemplary embodiment, process continues by removing the remaining portion 168 of the planarizing layer 160. For example, the planarizing layer 160 may be stripped by an etch process using an etchant selective to the removal of the planarizing layer 160 over the select gate material 144.

Next, an anisotropic etch is performed to define select gates 170 adjacent each stack gate structure 122, as shown in FIG. 9. Specifically, the select gate material 144 is etched, such as by a reactive ion etch (RIE) process. In an exemplary method, the select gate material 144 is polysilicon and is etched during a process etching all polysilicon components on the semiconductor substrate 102. As shown, the etch process exposes the select gate dielectric layer 140 previously underlying the trough 148. Further, the etch process forms the select gates 170 with substantially vertical and planar sidewalls 174 and substantially horizontal and planar upper surfaces 176 that are substantially perpendicular to the sidewalls 174. Also, each select gate 170 is formed with a thickness indicated by double headed arrow 178 that is substantially equal to thickness 154 (see FIG. 5). The stack gate structure 122 and select gate 170 form a stack gate nonvolatile memory device 180.

FIGS. 10-11 illustrate an alternative embodiment for forming select gates 170 in which the planarizing layer 160 is not utilized. In FIG. 10, the select gate material 144 of FIG. 5 is planarized such as by a chemical-mechanical planarization (CMP) process. As a result, the select gate material 144 is formed with a planar recessed surface 166. Similar to the process in FIG. 9, an anisotropic etch is performed in FIG. 11 to define select gates 170 adjacent each stack gate structure 122. For example, the select gate material 144 may be etched by a reactive ion etch (RIE) process. In an exemplary method, the select gate material 144 is polysilicon and is etched during a process etching all polysilicon components on the semiconductor substrate 102. As shown, the etch process exposes the select gate dielectric layer 140 previously underlying the trough 148. Further, the etch process forms the select gates 170 with substantially vertical and planar sidewalls 174 and substantially planar upper surfaces 176 that are substantially perpendicular to the sidewalls 174. Also, each select gate 170 is formed with a thickness indicated by double headed arrow 178 that is substantially equal to thickness 154 (see FIG. 5). The stack gate structure 122 and select gate 170 form a stack gate nonvolatile memory device 180.

In various embodiments, further processing of the partially completed integrated circuits of FIGS. 9 and 11 may include removal of the exposed select gate dielectric layer, spacer formation around the select gates, ion implantation processes to form source/drain regions and source/drain extension regions, formation of contacts, and formation of interconnect structures (e.g., lines and vias, metal layers, and interlayer dielectric material). In FIGS. 9 and 11, the partially fabricated integrated circuit 100 includes a stack gate nonvolatile memory device 180 formed with select gates 170 without defects, such as horns or sloping or non-planar surfaces. The processes described herein provide for formation of improved select gates 170 using relaxed processing parameters as compared to conventional processing.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

1. A method for fabricating an integrated circuit, the method comprising:
forming a stack gate structure overlying a semiconductor substrate;
forming a select gate material overlying the stack gate structure and the semiconductor substrate and including a gate portion having a planar surface overlying the stack gate structure and including a trough portion adjacent the stack gate structure; and
simultaneously etching the gate portion of the select gate material to a planar upper select gate surface and the trough portion of the select gate material to define a select gate with the planar upper select gate surface and with an exposed sidewall, wherein the select gate is adjacent the stack gate structure.

2. The method of claim 1 wherein forming the stack gate structure comprises forming a control gate and wherein forming the select gate material overlying the stack gate structure and the semiconductor substrate and including the gate portion having the planar surface overlying the stack gate structure and including the trough portion adjacent the stack gate structure comprises:
depositing the select gate material overlying the stack gate structure and the semiconductor substrate; and
recessing the select gate material and establishing the planar recessed surface overlying the control gate.

3. The method of claim 2 wherein recessing the select gate material and establishing the planar recessed surface over the control gate comprises planarizing the select gate material.

4. The method of claim 2 wherein recessing the select gate material and establishing the planar recessed surface over the control gate comprises:
forming a planarizing layer overlying the select gate material and having a planar top surface; and
recessing the planarizing layer and the select gate material to form the planar recessed surface, wherein the planar recessed surface is formed from the select gate material and the planarizing layer.

5. The method of claim 4 wherein forming the planarizing layer overlying the select gate material comprises forming a self-planarizing organic layer overlying the select gate material.

6. The method of claim 4 wherein forming the planarizing layer overlying the select gate material comprises forming photoresist overlying the select gate material.

7. The method of claim 4 further comprising removing a remaining portion of the planarizing layer and defining a trough in the select gate material overlying the trough portion of the select gate material, wherein simultaneously etching the gate portion of the select gate material to the planar upper select gate surface and the trough portion of the select gate material to define the select gate with the planar upper select gate surface and with the exposed sidewall comprises removing the trough portion of the select gate material.

8. The method of claim 4 wherein recessing the planarizing layer and the select gate material to form the planar recessed surface comprises non-selectively etching the planarizing layer and the select gate material.

9. The method of claim 1 wherein forming the select gate material overlying the stack gate structure and the semiconductor substrate and having the planar surface overlying the stack gate structure comprises:
depositing the select gate material overlying the stack gate structure and the semiconductor substrate; and
recessing the select gate material and establishing the planar recessed surface overlying the stack gate structure, wherein simultaneously etching the gate portion of the select gate material to the planar upper select gate surface and the trough portion of the select gate material to define the select gate with the planar upper select gate surface and with the exposed sidewall comprises removing the select gate material overlying the stack gate structure.

10. The method of claim 1 wherein forming the select gate material overlying the stack gate structure and the semiconductor substrate and including the gate portion having the planar surface overlying the stack gate structure and including the trough portion adjacent the stack gate structure comprises:
conformally depositing the select gate material overlying the stack gate structure and the semiconductor substrate; and
recessing the select gate material and establishing the planar recessed surface overlying the stack gate structure.

11. A method for fabricating an integrated circuit, the method comprising:
depositing a tunnel dielectric layer overlying a semiconductor substrate;
depositing a floating gate layer overlying the tunnel dielectric layer;
depositing an intergate dielectric layer overlying the floating gate layer;
depositing a control gate layer overlying the intergate dielectric layer;
depositing a cap layer overlying the control gate layer;
etching the cap layer, control gate layer, intergate dielectric layer, floating gate layer, and tunnel dielectric layer to form stack gate structures, wherein each stack gate structure includes a control gate and a floating gate;
depositing a select gate material including a gate portion overlying the stack gate structures and including a trough portion between adjacent stack gate structures and overlying the semiconductor substrate;
recessing the gate portion of the select gate material and forming the gate portion of the select gate material with a planar recessed surface; and
performing a select gate material etch process to anisotropically etch the planar recessed surface of the gate portion and the trough portion of the select gate material to define a select gate adjacent each stack gate structure.

12. The method of claim 11 wherein recessing the gate portion of the select gate material and forming the gate portion of the select gate material with the planar recessed surface comprises forming the select gate material with the planar recessed surface overlying the control gate.

13. The method of claim 11 wherein depositing the select gate material including the gate portion overlying the stack gate structures and including the trough portion between adjacent stack gate structures and overlying the semiconductor substrate comprises forming the select gate material with a planar upper surface overlying the stack gate structures, and wherein recessing the gate portion of the select gate material and forming the gate portion of the select gate material with the planar recessed surface comprises recessing the planar upper surface.

14. The method of claim 13 wherein recessing the gate portion of the select gate material and forming the gate portion of the select gate material with the planar recessed surface comprises:
forming a planarizing layer overlying the select gate material and having a planar top surface; and
recessing the planarizing layer and the select gate material to form the planar recessed surface, wherein the planar recessed surface is formed from the select gate material and the planarizing layer; and wherein the method further comprises removing a remaining portion of the planarizing layer and defining a trough in the select gate material between adjacent stack gate structures and overlying the trough portions of the select gate material wherein performing the select gate material etch process to anisotropically etch the planar recessed surface of the gate portion and the trough portion of the select gate material to define the select gate adjacent each stack gate structure comprises removing the trough portions of the select gate material.

15. The method of claim 14 wherein performing the select gate material etch process to anisotropically etch the planar recessed surface of the gate portion and the trough portion of the select gate material to define the select gate adjacent each stack gate structure comprises forming each select gate with a sidewall bounding the trough.

16. The method of claim 14 wherein forming the planarizing layer overlying the select gate material comprises forming a self-planarizing organic layer overlying the select gate material.

17. The method of claim 14 wherein forming the planarizing layer overlying the select gate material comprises forming photoresist overlying the select gate material.

18. The method of claim 14 wherein recessing the planarizing layer and the select gate material to form the planar recessed surface comprises non-selectively etching the planarizing layer and the select gate material.

19. The method of claim 11 wherein depositing the select gate material including the gate portion overlying the stack gate structures and including the trough portion between adjacent stack gate structures and overlying the semiconductor substrate comprises depositing polysilicon overlying the stack gate structures and the semiconductor substrate.

20. A method for fabricating an integrated circuit including a non-volatile memory, the method comprising:
forming a stack gate structure including control gate overlying a floating gate and overlying a semiconductor substrate;
conformally depositing a select gate material overlying the stack gate structure and the semiconductor substrate, wherein the select gate material includes a gate portion overlying the stack gate structure and a trough portion adjacent the stack gate structure, and wherein the gate portion of the select gate material has substantially vertical wall defining a lateral thickness from the stack gate structure;
recessing the gate portion of the select gate material and forming the gate portion of the select gate material with a planar recessed surface; and
while exposing the planar recessed surface of the gate portion of the select gate material, anisotropically etching the trough portion of the select gate material to define a select gate adjacent the stack gate structure.
